(19) United States
(12) Patent Application Publication
(10) Pub. No.: US 2003/0123574 A1
(43) Pub. Date: Jul. 3, 2003

(54) System and method for robust tone detection

(76) Inventors: Richard Corpuz Simeon, Spring City, PA (US); Damian Charles Hamme, Chalfont, PA (US)

Correspondence Address: HUNTON & WILLIAMS, INTELLECTUAL PROPERTY DEPARTMENT, 1900 K STREET, N.W., SUITE 1200, WASHINGTON, DC, 20006-1109, US

(21) Appl. No.: 10/029,877

(22) Filed: Dec. 31, 2001

(51) Int. Cl. H04J 3/12; H04L 27/06; H03D 1/00

(52) U.S. Cl. 375/340; 370/526

(57) ABSTRACT

A tone detection device is provided which includes a Fourier Transform means for performing a Fourier Transform on an incoming signal. The Fourier Transform means generates a frequency spectrum of the incoming signal. A normalizing means receives the generated frequency spectrum and normalizes the spectrum for magnitude. The normalizing means then generates a normalized frequency spectrum. An integrator means receives the normalized frequency spectrum and generates a mean of the normalized frequency spectrum over time. A comparator means then determines whether the mean of the normalized frequency spectrum exceeds a predetermined threshold value. If so, a signal is generated indicating that a tone is detected. If the mean of the normalized frequency spectrum does not exceed the predetermined threshold value, a signal is generated indicating that no tone is detected.

### FIELD OF INVENTION

The present invention relates generally to communication systems and, in particular, to systems for transmitting and receiving signals configured to include at least one tone. More particularly, the present invention relates to systems and methods for detecting the presence of such tones in the received signal.

### BACKGROUND OF INVENTION

Modern telecommunications systems and computer network systems are required to detect various types of audio signals for communication with other system elements. The most common of these audio signals include Dual Tone Multi Frequency (DTMF) signals such as the touch tones generated by pressing a telephone keypad. Each tone sounded within the DTMF system is a combination two discrete tones, one generated at a high frequency and the second generated at a low frequency. Of course, in order for generated tones to be useful in any telecommunications system, they must be properly detected and decoded. In the past, the transmission of DTMF signals was typically limited to periods preceding the actual relay of voice or data (e.g., fax) traffic over the system. Limiting DTMF signals to such a period enabled designers to maximize the signal to noise ratio (SNR) for the tone, thereby minimizing or eliminating the likelihood of conflict between the DTMF signals and other signals being carried by the system (e.g., the voice or data traffic). This, in turn, greatly simplified the tone detection process.

Unfortunately, modern telecommunications systems require that many different types of information be transmitted simultaneously, such as voice or data traffic. Consequently, with the increase in transmitted information as well as additional distortion due to attentuation, channel noise, radiation, etc., the SNR's of the system environments have substantially decreased, thereby increasing the difficulty of the tone detection process. The most common effects of such noise are “talk-off”, where a legitimate DTMF signal is missed by the detector and “talk-down”, where the detector erroneously interprets noise as a DTMF signal. From a tone detection standpoint, robust tone detection requires the ability to discern a stationary tone amongst stationary and non-stationary noise. This trait is of particular importance in digital communications receivers, where tones are generally used to indicate important state transitions or convey synchronization information from one device to another device. Although numerous attempts have been made to accurately detect tones in these systems, conventional approaches have resulted in unacceptable performance, suffering from excessive cost, processing requirements, and reduced accuracy.

Therefore, there is a need in the art of telecommunications systems for a system and method for providing robust tone detection.

### SUMMARY OF INVENTION

The present invention overcomes the problems noted above, and provides additional advantages, by exploiting the differences between a singular tone and background noise; namely, the high correlation properties of tones and the disparate correlation qualities of noise. In particular, a tone detection device in accordance with one embodiment of the present invention includes a Fourier Transform means for performing a Fourier Transform on an incoming signal. The Fourier Transform means generates a frequency spectrum of the incoming signal. A normalizing means receives the generated frequency spectrum and normalizes the spectrum for magnitude. The normalizing means then generates a normalized frequency spectrum. An integrator means receives the normalized frequency spectrum and generates a mean of the normalized frequency spectrum over time. A comparator means then determines whether the mean of the normalized frequency spectrum exceeds a predetermined threshold value. If so, a signal is generated indicating that a tone is detected. If the mean of the normalized frequency spectrum does not exceed the predetermined threshold value, a signal is generated indicating that no tone is detected.

### BRIEF DESCRIPTION OF THE DRAWINGS

FIG. 1 is a block diagram illustrating a tone detector according to one embodiment of the present invention;

FIG. 2 is a block diagram of a DSP in accordance with one embodiment of the present invention; and

FIG. 3 is a block diagram schematically illustrating one embodiment of the normalizer of FIG. 2.

### DETAILED DESCRIPTION OF THE PREFERRED EMBODIMENTS

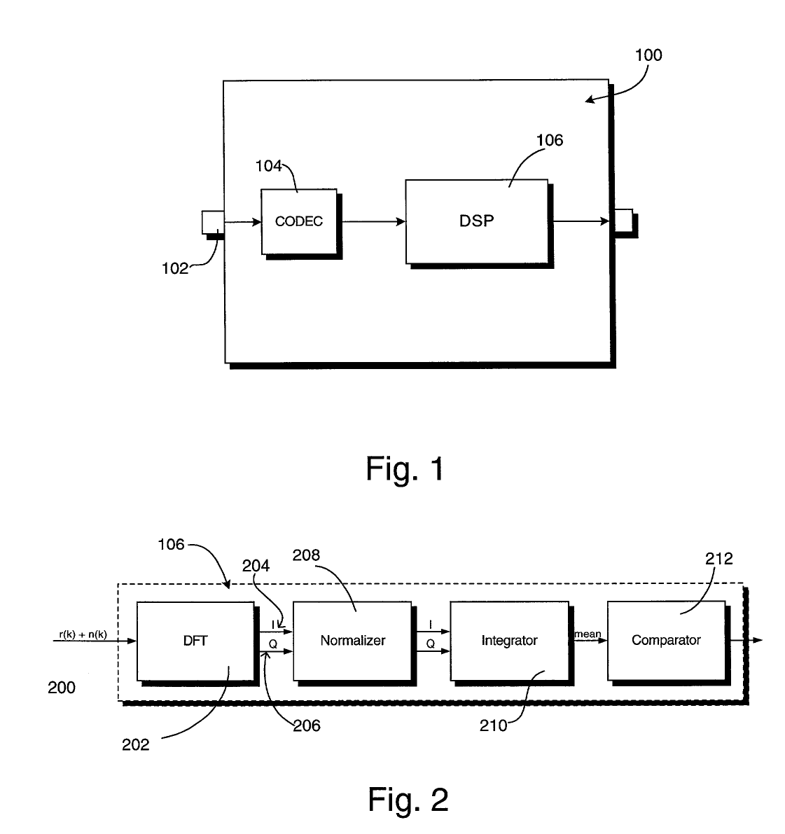

Referring generally to the figures and, in particular, to FIG. 1, there is shown a block diagram illustrating a tone detector 100 according to one embodiment of the present invention. In particular, the tone detector 100 preferably includes at least one input or port 102 for receiving analog or digital signals. In one embodiment, the input 102 is configured to receive a communications medium such as a telephone phone line or the like. Further, the tone detector 100 also preferably includes a coder/decoder (“codec”) 104 operatively connected to the input 102 for receiving analog signals and converting them into a digital format. The codec 104 preferably samples the analog signal at 1.104 Mhz and utilizes pulse code modulation (“PCM”) or other suitable techniques to produce corresponding digital data. The codec 104 preferably includes at least a linear analog to digital (“A/D”) converter and associated circuitry to perform the above-described conversion. Once analog to digital conversion has been performed, digital data or digital samples are generated based upon the analog signal received at input 102. It should be understood that the present invention is also applicable in systems wherein the signals received at input 102 comprise digital signals which need not be converted by codec 104. Accordingly, in these systems, codec 104 is not required.

The tone detector 100 also preferably includes at least one digital signal processor (“DSP”) 106 operatively connected to the codec 104 (or the input 102 in all digital environments). In one embodiment, it is envisioned that both the codec 104 and the DSP 106 are jointly included on a single silicon chip. DSP 106 operates on the digital signal generated by codec 104 in a manner described in further detail below to determine the presence of a tone in the signal.

Referring now to FIG. 2, there is shown a block diagram of DSP 106 in accordance with one embodiment of the present invention. In particular, DSP 106 includes circuitry for performing a plurality of discrete operations on the converted (or received) digital signal. For the purposes of clarity, each of these operations has been designated by an individual block element in the diagram. It should be understood that in an actual implementation, each of these elements would preferably be combined within the integrated circuitry of the DSP and would typically not constitute stand alone circuit elements. By designating an individual block element for each operation, the inventive system can be better explained.

DSP 106 includes circuitry means 202 for performing a Discrete Fourier Transform (“DFT”) on the incoming signal 200. Referring to the input signal 200, let r(k) be the tone to be detected, and n(k) be additive white Gaussian noise (AWGN), where k is the symbol index. A symbol is a collection of N samples used to form the frequency-domain vectors. The initially converted digital signal is typically formed by PCM or similar time-domain based methodologies. Consequently, in order to examine the frequency aspects of the signal, it is desirable to transform the signal into discrete frequency-domain vectors representing specific frequency ranges, commonly referred to as bins. This is accomplished through some form of Fourier Transformation. Although DFT is preferably implemented and described herein, other frequency-domain transformations such as Fast Fourier Transform (“FFT”) and Goertzel Transform may be similarly used to obtain the desired frequency-domain vector(s).

The implementation of DFT to a digital signal transforms the time-domain signal into a plurality of frequency bins relating to the specific frequencies ranges being detected. In one embodiment, the tone detector operates to determine whether a single particular tone is contained within a signal. In this embodiment, it is only necessary to generate a single frequency bin relating to the single specific frequency range being detected. As is known in the art, a DFT generated frequency vector is a complex signal containing both magnitude and phase components 204 and 206.

In accordance with one embodiment of the present invention, the frequency-domain (i.e., transformed) representations of r(k) and n(k) are:

$$\begin{matrix}{R}_{k} ( η ) = {A}_{r} {ⅇ}^{j {θ}_{r}} \\ = {A}_{r} [ cos ( {θ}_{r} ) - j sin ( {θ}_{r} ) ]\end{matrix}$$

$$\begin{matrix}{N}_{k} ( η ) = {A}_{n} ( k ) {ⅇ}^{j {θ}_{n} ( k )} \\ = {A}_{n} ( k ) [ cos ( {θ}_{n} ) - j sin ( {θ}_{n} ) ]\end{matrix}$$

where η is the bin number, A is the amplitude and θ is the phase angle. Note that R(η) is independent of k, since the tone portion of the incoming signal remains constant over all symbols. In terms of the real (In-phase) and imaginary (Quadrature) components, for Rₖ(η) this equates to:

I[Rₖ(η)]=Aᵣcos(θ)

and

Q[Rₖ(η)]=Aᵣsin(θᵣ)

and for Nₖ(η), this equates to:

I[Nₖ(η)]=Aₙ(k)cos(θₙ)

and

Q[Nₖ(η)]=Aₙ(k)sin(θᵣ)

Once the signal has been transformed into the frequency-domain, the complex signal is delivered to normalizer circuitry 208, where the magnitude of the complex signal is normalized to a predetermined amplitude. The normalizer 208 equalizes the amplitude of whatever signal enters the frequency bin, thus eliminating the amplitude term. Without loss of generality, it has been determined that the amplitude may be normalized to unity (i.e., 1). By using the normalizer, the tone detector removes the power sensitivity and concentrates on the correlation of the angle (i.e., phase) of the bin vector.

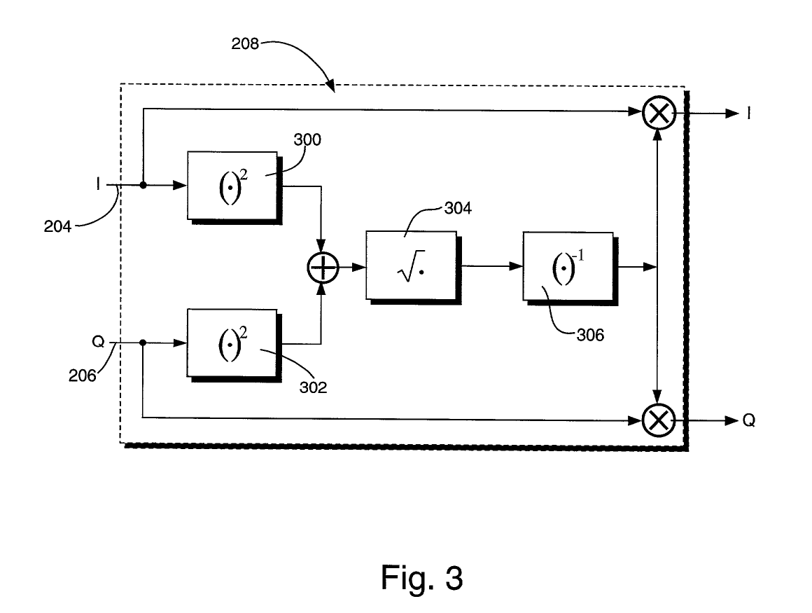

Referring now to FIG. 3, there is shown a block diagram schematically illustrating one embodiment of the normalizer 208 of FIG. 2. In particular, it can be seen that the real and imaginary components 204 and 206 from DFT 202 are received. In blocks 300 and 302, the real and imaginary components are independently squared. The squared values are then added and the square root of the combined value is obtained in block 304. This value represents the magnitude of the incoming signal. In block 306, the magnitude value is inverted and each of the real and imaginary components are multiplied by this inverted value. The result of these computations is the normalization of the incoming signal to unity.

Returning now to FIG. 2, once the signal has been normalized both the remaining real and imaginary components are passed to integrator circuitry 210. Integrator circuitry operates to compute the statistical mean of the normalized incoming signal. It can be shown that N(η), after normalization, has a uniform phase distribution for AWGN. The probability density function for this distribution can be expressed as:

$${p}_{{θ}_{n}} ( {θ}_{n} ) = \frac{1}{2 π}$$

This particular distribution, when applied to N(η) (i.e., the noise), has a statistical mean of zero with respect to the phase angle θ. A stationary tone (i.e., R(η)), however, has constant amplitude and phase, and thus the statistical mean of R(η) is in fact R(η) (i.e., there is no randomness associated with R(η)). The integrator circuitry 210 effectively averages the output of the normalizer 208 by taking a running sum of the normalized signal and dividing this sum by the number of samples taken to arrive at the complex-valued average of the normalizer.

Once the statistical mean of the signal has been determined, a signal representative thereof is generated and passed to comparator circuitry 212. Given that the statistical mean of R(η) and N(η) are different, the comparator circuitry 212 operates to exploit this property to distinguish the presence of a correlated signal (i.e., a tone). The comparator 212 examines the statistical mean generated by the integrator 210 and determines whether the value exceeds a predetermined threshold. Uncorrelated noise will yield a mean of zero, while a correlated tone will yield a non-zero mean. Preferably, the threshold is a non-zero value sufficient to maximize the probability of the detection while simultaneously minimizing the probability of false alarm. In one embodiment, the threshold value is 0.5.

In one embodiment, the comparator threshold is established by examining the magnitude of the signal generated by the integrator 210. As with any detection scheme, a study on the effects of noise on the robustness of the system is necessary to help determine the comparator threshold given a desired probability of detection and/or false alarm (P_{d} and P_{fa}, respectively). To simplify analysis, the SNR is used to evaluate the system probabilities. Determination of P_{d} and P_{fa} requires the probability density functions p₀(γ) and p₁(γ), which are the probability density functions of the normalized noise and noise+tone signals, respectively. Because the normalizer 208 acts to remove the effects of amplitude from the analysis, it is not the power of the noise itself that dictates the quiescent noise floor of the detector, but rather the phase coherency of the integrator output. This simplifies calculation of p₀(γ) but unfortunately complicates calculation of p₁(γ). However, since the present invention utilizes the magnitude of γ as the comparator input, mag(γ) becomes the focus of the analysis.

For p₀(γ|N) (the probability of γ given N samples), it can be shown that the distribution resembles a two-dimensional Gaussian distribution. The variance of p₀(γ|N) can be expressed as:

$${σ}_{n}^{2} = \frac{{A}_{n}}{N}$$

Thus, a bigger value of N reduces the variance of γ when only AWGN is present. This would allow the threshold to be assigned a more aggressive value for a greater P_{d} without sacrificing a larger P_{fa}. Observation of p₁(γ|N) shows a distribution symmetric about the phase angle of the tone, but forming a Rayleigh distribution in magnitude, for small SNR. This Rayleigh distribution can be expressed as:

$${p}_{γ} ( γ ) = \frac{γ}{{m}^{2}} {ⅇ}^{\frac{- γ}{2 {m}^{2}}} , for γ > 0$$

where, the mean is

$$m \sqrt{\frac{π}{2}} .$$

For large SNR and large N, p₁(γ|N) is more Guassian.

The tone detector of the present invention provides robust tone detection that is immune to variations in tone and noise power. In addition, the detector of the present invention enables accurate tone detection without requiring immense processing resources. While the foregoing description includes many details and specificities, it is to be understood that these have been included for purposes of explanation only, and are not to be interpreted as limitations of the present invention. Many modifications to the embodiments described above can be made without departing from the spirit and scope of the invention, as is intended to be encompassed by the following claims and their legal equivalents.

What is claimed is:

1. A system for detecting the presence of a tone within a signal, comprising:
Fourier Transform means for performing a Fourier Transform on an incoming signal,
wherein the Fourier Transform means generates a frequency spectrum for the incoming signal;
normalizing means for receiving the generated frequency spectrum and normalizing the spectrum for magnitude,
wherein the normalizing means generates a normalized frequency spectrum;
integrator means for receiving the normalized frequency spectrum and generating a mean of the normalized frequency spectrum; and
comparator means for determining whether the mean of the normalized frequency spectrum exceeds a predetermined threshold value,
if said mean exceeds the predetermined threshold value, the comparator means generates a signal indicating that a tone is detected,
if said mean does not exceed the predetermined threshold value, the comparator means generates a signal indicating that no tone is detected.

2. The system of claim 1, further comprising:
a codec for receiving an incoming analog signal and converting it to a corresponding digital signal; and
a digital signal processor for receiving the converted signal,
wherein the digital signal processor includes circuitry comprising the Fourier Transform means, the normalizing means, the integrator means, and the comparator means.

3. The system of claim 1, wherein the Fourier Transform means generates discrete frequency bins representing specific frequency ranges for the incoming signal and wherein a single frequency bin is generated relating to the tone being detected.

4. The system of claim 3, further comprising:
a tone portion of the incoming signal for the frequency bin relating to the tone being detected is represented by the expression:
$$\begin{matrix}{R}_{k} ( η ) = {A}_{r} {ⅇ}^{j {θ}_{r}} \\ = {{A}_{r} [ cos ( {θ}_{r} ) - j sin ( {θ}_{r} ) ]}^{′}\end{matrix}$$
where η is the bin number, Aᵣ is the amplitude of the tone portion, and θ is the phase angle; and
a noise portion of the incoming signal for the frequency bin relating to the tone being detected is represented by the expression:
$$\begin{matrix}{N}_{k} ( η ) = {A}_{n} ( k ) {ⅇ}^{j {θ}_{n} ( k )} \\ = {{A}_{n} ( k ) [ cos ( {θ}_{n} ) - j sin ( {θ}_{n} ) ]}^{′}\end{matrix}$$
where Aₙ is the amplitude of the noise portion, θ is the phase angle, and k is a symbol index.

5. The system of claim 1, wherein:
a frequency spectrum for the incoming signal includes a real component and an imaginary component; and
the normalizing means generates a normalized frequency spectrum by multiplying an inverted magnitude of the incoming signal by each of the real and imaginary components of the frequency spectrum.

6. The system of claim 1, wherein the predetermined threshold value is 0.5.

7. The system of claim 1, wherein the Fourier Transform means perform a Discrete Fourier Transform on the incoming signal.

8. The system of claim 1, wherein the Fourier Transform means perform a Fast Fourier Transform on the incoming signal.

9. The system of claim 1, wherein the Fourier Transform means perform a Goertzel Transform on the incoming signal.

10. A method for detecting the presence of a tone within a signal, comprising the steps of:
generating a frequency spectrum for an incoming signal;
normalizing the generated frequency spectrum for magnitude;
generating a normalized frequency spectrum;
generating a mean of the normalized frequency spectrum;
determining whether the generated mean of the normalized frequency spectrum exceeds a predetermined threshold value;
generating a signal indicating that a tone is detected if it is determined that the mean exceeds the predetermined threshold value; and
generating a signal indicating that no tone is detected if it is determined that the mean does not exceed the predetermined threshold value.

11. The method of claim 10, further comprising the steps of:
receiving an incoming analog signal into a codec;
converting the incoming analog signal into a corresponding digital signal; and
receiving the digital signal into a digital signal processor,
wherein the digital signal processor performs detects the presence of a tone in the digital signal.

12. The method of claim 10, further comprising the step of generating discrete frequency bins representing specific frequency ranges for the incoming signal, wherein a single frequency bin is generated relating to the tone being detected.

13. The method of claim 12, further comprising the steps of:
representing a tone portion of the incoming signal for the frequency bin relating to the tone being detected by the expression:
$$\begin{matrix}{R}_{k} ( η ) = {A}_{r} {ⅇ}^{j {θ}_{r}} \\ = {{A}_{r} [ cos ( {θ}_{r} ) - j sin ( {θ}_{r} ) ]}^{′}\end{matrix}$$
where η is the bin number, Aᵣ is the amplitude of the tone portion, and θ is the phase angle; and
representing a noise portion of the incoming signal for the frequency bin relating to the tone being detected by the expression:
$$\begin{matrix}{N}_{k} ( η ) = {A}_{n} ( k ) {ⅇ}^{j {θ}_{n} ( k )} \\ = {{A}_{n} ( k ) [ cos ( {θ}_{n} ) - j sin ( {θ}_{n} ) ]}^{′}\end{matrix}$$
where Aₙ is the amplitude of the noise portion, θ is the phase angle, and k is a symbol index.

14. The method of claim 10, further comprising the step of generating a normalized frequency spectrum by multiplying an inverted magnitude of the incoming signal by each of the real and imaginary components of the frequency spectrum.

15. The method of claim 10, wherein the predetermined threshold value is 0.5.

16. The method of claim 10, wherein the step of generating a frequency spectrum for an incoming signal is performed by Fourier Transform means.

17. The method of claim 16, wherein the Fourier Transform means perform a Discrete Fourier Transform on the incoming signal.

18. The method of claim 16, wherein the Fourier Transform means perform a Fast Fourier Transform on the incoming signal.

19. The method of claim 16, wherein the Fourier Transform means perform a Goertzel Transform on the incoming signal.

20. A programmable digital signal processor including a computer readable storage medium incorporating instructions for detecting the presence of a tone within a signal, the instructions comprising:
one or more instructions for generating a frequency spectrum for an incoming signal;
one or more instructions for normalizing the generated frequency spectrum for magnitude;
one or more instructions for generating a normalized frequency spectrum;
one or more instructions for generating a mean of the normalized frequency spectrum;
one or more instructions for determining whether the generated mean of the normalized frequency spectrum exceeds a predetermined threshold value;
one or more instructions for generating a signal indicating that a tone is detected if it is determined that the mean exceeds the predetermined threshold value; and
one or more instructions for generating a signal indicating that no tone is detected if it is determined that the mean does not exceed the predetermined threshold value.

21. The programmable digital signal processor of claim 20, further comprising one or more instructions for generating discrete frequency bins representing specific frequency ranges for the incoming signal, wherein a single frequency bin is generated relating to the tone being detected.

22. The programmable digital signal processor of claim 21, further comprising:
one or more instructions for representing a tone portion of the incoming signal for the frequency bin relating to the tone being detected by the expression:
$$\begin{matrix}{R}_{k} ( η ) = {A}_{r} {ⅇ}^{j {θ}_{r}} \\ = {{A}_{r} [ cos ( {θ}_{r} ) - j sin ( {θ}_{r} ) ]}^{′}\end{matrix}$$
where η is the bin number, Aᵣ is the amplitude of the tone portion, and θ is the phase angle; and
one or more instructions for representing a noise portion of the incoming signal for the frequency bin relating to the tone being detected by the expression:
$$\begin{matrix}{N}_{k} ( η ) = {A}_{n} ( k ) {ⅇ}^{{jθ}_{n} ( k )} \\ = {A}_{n} ( k ) [ cos ( {θ}_{n} ) - j s in ( {θ}_{n} ) ] ’\end{matrix}$$
where Aₙ is the amplitude of the noise portion, θ is the phase angle, and k is a symbol index.

23. The programmable digital signal processor of claim 20, further comprising one or more instructions for generating a normalized frequency spectrum by multiplying an inverted magnitude of the incoming signal by each of the real and imaginary components of the frequency spectrum.

24. The programmable digital signal processor of claim 20, wherein the predetermined threshold value is 0.5.

25. The programmable digital signal processor of claim 20, wherein the one or more instructions for generating a frequency spectrum for an incoming signal is performed by Fourier Transform means.

26. The programmable digital signal processor of claim 25, wherein the Fourier Transform means perform a Discrete Fourier Transform on the incoming signal.

27. The programmable digital signal processor of claim 25, wherein the Fourier Transform means perform a Fast Fourier Transform on the incoming signal.

28. The programmable digital signal processor of claim 25, wherein the Fourier Transform means perform a Goertzel Transform on the incoming signal.
